(19) United States
(12) Patent Application Publication
(10) Pub. No.: US 2018/0333755 A1
(43) Pub. Date: Nov. 22, 2018

(54) SUBSTRATE TREATING APPARATUS AND SUBSTRATE TREATING METHOD

(71) Applicant: SEMES CO., LTD., Cheonan-si (KR)

(72) Inventors: Su Hyung LEE, Hwaseong-si (KR); Youngje Um, Busan (KR)

(73) Assignee: SEMES CO., LTD., Cheonan-si (KR)

(21) Appl. No.: 15/982,005

(22) Filed: May 17, 2018

(30) Foreign Application Priority Data
May 17, 2017 (KR) 10-2017-0060918

(51) Int. Cl. B08B 7/04; B08B 7/00; H01L 21/67

(52) U.S. Cl. CPC B08B 7/04; B08B 7/0071; H01L 21/67063; H01L 21/67051; B08B 7/0021

(57) ABSTRACT

Provide are a substrate treating apparatus and a substrate treating method. The substrate treating apparatus comprises a chamber, a substrate supporting member which is positioned in the chamber to support the substrate, a spray member which supplies a rinse liquid to the substrate, a depressurizing line which is used to depressurize the chamber, and a controller which vaporizes the rinse liquid by depressurizing the chamber through the depressurizing line after supplying the rinse liquid in a liquid phase.

### CROSS-REFERENCE TO RELATED APPLICATIONS

This application claims priority under 35 U.S.C. § 119 to Korean Patent Application No. 10-2017-0060918 filed on May 17, 2017, in the Korean Intellectual Property Office, the disclosures of which are incorporated by reference herein in their entireties.

### BACKGROUND

Embodiments of the inventive concept relate to a substrate treating apparatus and a substrate treating method.

To fabricate a semiconductor device and a liquid crystal display panel, various processes, such as a photolithography, etching, ashing, thin film deposition, and cleaning processes have been performed. Among them, the etching process, which is to remove an unnecessary region from a thin film formed on a substrate, requires a higher selective ratio and a higher etching rate with respect to the thin film.

In general, the etching process or the cleaning process is mainly performed by sequentially performing a chemical treatment step, a rinse treatment step, and a dry treatment step. According the chemical treatment step, the thin film formed on the substrate is etched or chemicals are supplied to the substrate to remove foreign matters from the substrate. According to the rinse treatment step, a rinse liquid, which is pure water, is supplied onto the substrate. In the procedure of drying the rinse liquid, the surface tension made by the rinse liquid is applied to the substrate. As finer patterns are formed on the substrate, the risk of breaking the pattern due to the surface tension may be increased.

### SUMMARY

Embodiments of the inventive concept provide a substrate treating apparatus and a substrate treating method, capable of efficiently treating a substrate.

Embodiments of the inventive concept provide a substrate treating apparatus and a substrate treating method, capable of efficiently drying a rinse liquid applied to a substrate.

According to an exemplary embodiment of the inventive concept, there may be provided an apparatus of treating a substrate comprising a chamber; a substrate supporting member which is positioned in the chamber to support the substrate, a spray member which supplies a rinse liquid to the substrate, a depressurizing line which is used to depressurize the chamber, and a controller which vaporizes the rinse liquid by depressurizing the chamber through the depressurizing line after supplying the rinse liquid in a liquid phase.

In addition, the spray member may supply a rinse liquid heated to a set temperature.

In addition, the controller may control the spray member to supply the rinse liquid in a first supply step of supplying the rinse liquid to the substrate and in a second supply step of supplying a rinse liquid heated to a temperature higher than a temperature of the rinse liquid in the first supply step.

Further, the apparatus may further comprise a pressurizing line connected with the chamber to supply pressurizing gas, which is used for pressurizing an inner part of the chamber, to the inner part of the chamber.

In addition, a line heater may be provided on the pressurizing line to heat the pressurizing gas.

In addition, the pressurizing gas, which is supplied to the inner part of the chamber, may be provided in a state that the pressurizing gas is heated to a set temperature.

Further, the controller may control the pressurizing line such that internal pressure of the chamber is higher than atmospheric pressure and lower than critical pressure of the rinse liquid, when supplying the rinse liquid.

In addition, the rinse liquid may have a temperature higher than a boiling point under atmosphere pressure and lower than a boiling point under internal pressure of the chamber.

In addition, the rinse liquid may be pure water

In addition, the rinse liquid may be isopropyl alcohol.

Further, the spray member may comprise a spray nozzle which discharges the rinse liquid to the substrate; a rinse liquid supply unit which supplies the rinse liquid; and a supply pipe which connects the rinse liquid supply unit with the spray nozzle. Internal pressure of the rinse liquid supply unit and the supply pipe may have pressure higher than atmospheric pressure.

Further, the substrate supporting member may comprise a heater to heat the rinse liquid applied to the substrate.

According to an exemplary embodiment of the inventive concept, there may be provided a method for treating the substrate, comprising positioning a substrate in a chamber having pressure higher than atmospheric pressure; supplying, to the substrate, a rinse liquid, which is heated to a temperature higher than a boiling point under atmospheric pressure, in a liquid phase; and vaporizing the rinse liquid by depressurizing the chamber.

In addition, internal pressure of the chamber may be provided to be lower than critical pressure of the rinse liquid.

In addition, the rinse liquid may be pure water

In addition, the rinse liquid may be isopropyl alcohol.

Further, the pressurizing of the chamber may be performed by supplying heated inert gas.

According to an exemplary embodiment, there may be provided a method for treating a substrate, comprising supplying a rinse liquid to the substrate; supplying a rinse liquid, which is heated, in a state that internal pressure of the chamber is higher than atmospheric pressure; and vaporizing the rinse liquid by depressurizing the chamber.

### BRIEF DESCRIPTION OF THE FIGURES

The above and other objects and features of the inventive concept will become apparent by describing in detail exemplary embodiments there of with reference to the accompanying drawings.

FIG. 1 is a view illustrating a substrate treating apparatus, according to an embodiment of the inventive concept;

FIG. 2 is a view illustrating a process chamber, according to the inventive concept;

FIG. 3 is a view illustrating a pipe relation of a spray member;

FIG. 4 is a view illustrating the control relation of a process module;

FIG. 5 is a view illustrating the procedure of rinsing and drying a substrate; and

FIG. 6 is a view illustrating a vaporization graph of a part in which the drying procedure is performed.

### DETAILED DESCRIPTION

Hereinafter, an embodiment of the inventive concept will be described in more detail with reference to the accompanying drawings. The embodiments of the inventive concept may be modified in various forms, and the scope of the inventive concept should not be construed to be limited by the embodiments of the inventive concept described in the following. The embodiments of the inventive concept are provided to describe the inventive concept for those skilled in the art more completely. Accordingly, the shapes and the like of the components in the drawings are exaggerated to emphasize clearer descriptions.

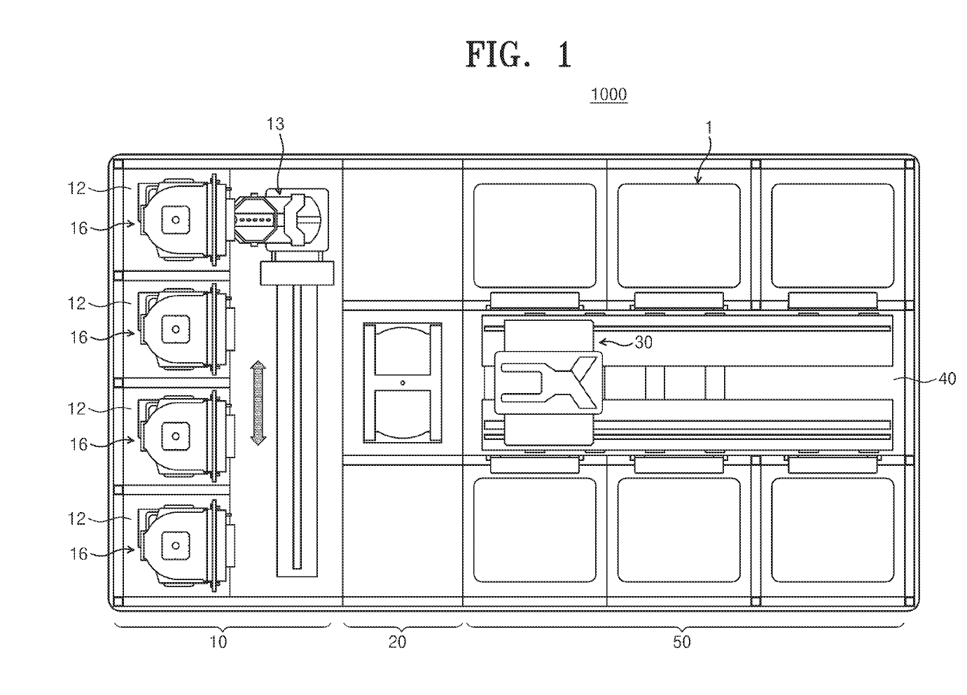

FIG. 1 is a view illustrating a substrate treating apparatus, according to an embodiment of the inventive concept.

Referring to FIG. 1, according to inventive concept, a substrate treating apparatus 1000 may comprise an index unit 10, a buffer unit 20, and a treatment unit 50. The index unit 10, the buffer unit 20, and the treatment unit 50 may be arranged in a line. Hereinafter, the arrangement direction of the index unit 10, the buffer unit 20, and the treatment unit 50 will be referred to a first direction, a direction perpendicular to the first direction when viewed from the top will be referred to a second direction, and a direction normal to a plane including the first direction and the second direction will be referred to a third direction.

The index unit 10 is arranged in the front portion of the substrate treating apparatus 1000 in the first direction. The index unit 10 comprises four load ports 12 and one index robot 13.

The four load ports 12 are arranged in the front portion of the index unit 10 in the first direction. A plurality of load ports 12 are provided and arranged in the second direction. The number of the load ports 12 may be varied depending on the process efficiency and the foot print condition of the substrate treating apparatus 1000. Carriers 16 (e.g., cassettes, front opening unified pods (FOUP), or the like) are positioned in the load ports 12 while receiving substrates “W” to be provided to a process and substrates “W” subject to the process treatment. The carriers 16 have a plurality of slots to receive the substrates “W” while arranging the substrates “W” horizontally to the ground surface.

The index robot 13 is arranged in the first direction to be adjacent to the load port 12. The index robot 13 is installed between the load port 12 and the buffer unit 20. The index robot 13 transfers the substrate “W”, which stands by at an upper layer of the buffer unit 20, to the carrier 16 or transfers the substrate “W”, which stands by in the carrier 16, to a lower layer of the buffer unit 20.

The buffer unit 20 is installed between the index unit 10 and the treatment unit 50. The buffer unit 20 temporarily stores a substrate “W” to be provided to a process before transferred by the index robot 13 or a substrate “W” completely subject to the process treatment before transferred by a main transfer robot 30 such that the substrate “W” stands by.

The main transfer robot 30 is positioned at a transfer chamber 40 to transfer a substrate “W” between each process module 1 and the buffer unit 20. The main transfer robot 30 transfers, to each process module 1, a substrate “W” to be provided for a process, which stands by in the buffer unit 20, and transfers, to the buffer unit 20, a substrate “W” completely subject to the process treatment

The transfer chamber 40 is provided to extend in the first direction and has a passage for the movement of the main transfer robot 30. Process modules 1 are arranged at both sides of the transfer chamber 40 in the first direction while facing each other. The main transfer robot 30 moves in the first direction inside the transfer chamber 40 and a moving rail is installed such that the main transfer robot 30 moves to upper and lower layers of the process module 1 and to upper and lower layers of the buffer unit 20.

Process modules 1 are arranged at both sides or at one side of the moving passage 40 such that the process modules 1 are adjacent to the moving passage 40 on which the main transfer robot 30 is installed. Although the substrate treating apparatus 1000 may comprise a plurality of process modules 1 provided at upper and lower layers, the number of the process modules 1 may be increased or decreased depending on the process efficiency and the foot print condition of the substrate treating apparatus 1000. Each process module 1 comprise an independent chamber 800. Accordingly, a process of treating a substrate “W” may be independently performed inside the substrate treating apparatus 1000.

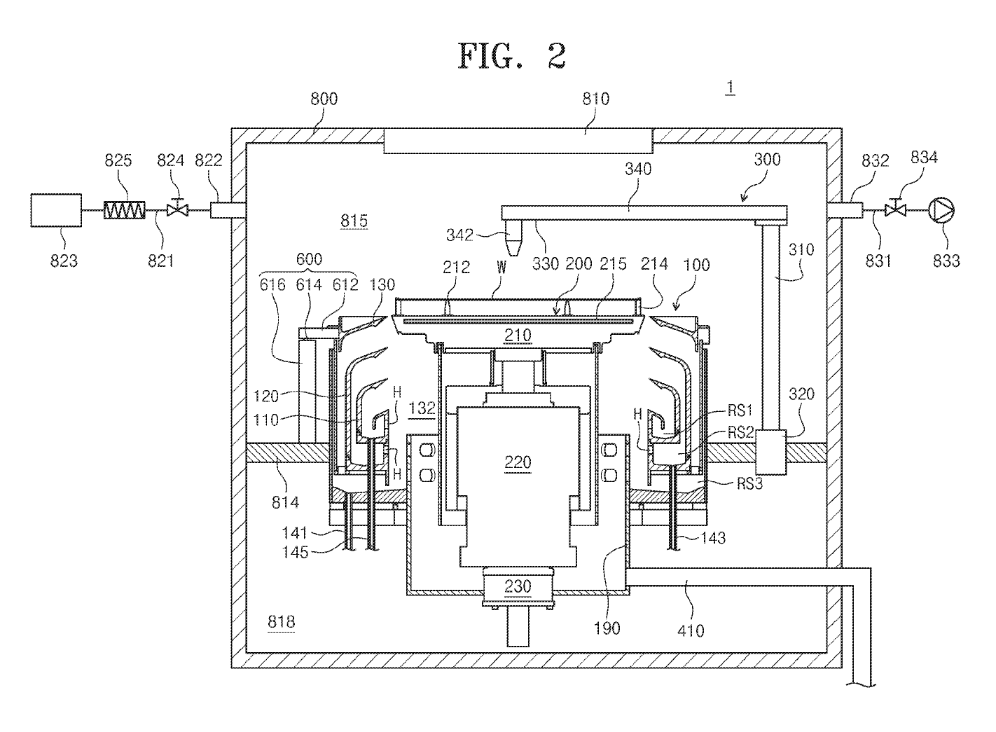

FIG. 2 is a view illustrating the process module, according to the inventive concept.

Although description will be made regarding a semiconductor substrate as a substrate “W” treated by the process module 1 according to the present embodiment, the inventive concept is not limited thereto. For example, the inventive concept is applicable to various types of substrate “W” such as a glass substrate.

Referring to FIG. 2, according to the inventive concept, the process module 1 comprises the chamber 800, a treatment container 100, a substrate supporting member 200, a spray member 300, and an exhaust line 410.

The chamber 800 provides a sealed inner space. The chamber 800 may be partitioned into a process region 815 and a maintenance region 818 by a partition 814. Although some elements are illustrated in drawings, the maintenance region 818 is a space in which recovery lines 141, 143, and 145 connected with the treatment container 100 and the exhaust line 410 are positioned. It is preferred that the maintenance region 818 is separated from the process region 815 in which the substrate “W” is treated.

The treatment container 100 is provided in the shape of a tub having an open upper portion to provide a process space for treating the substrate “W”. The open top surface of the treatment container 100 is provided as a passage to introduce or withdraw the substrate “W” into or out of the treatment container 100. The substrate supporting member 200 is positioned in the process region 815. The substrate supporting member 200 supports and rotates the substrate “W” when the process is performed.

The treatment container 100 is provided at an upper portion there of with first, second, and third suction ducts 110, 120, and 130 having annular shapes and provided in multiple stages to introduce or suck a chemical liquid and gas scattered on the substrate “W” which rotates. The first, second, and third suction ducts 110, 120, and 130 having annular shapes have exhaust holes H communicating with one common annular space (corresponding to a lower space of the treatment container 100). An exhaust duct 190 is provided at the lower portion of the treatment container 100 and connected with an exhaust line 410.

In detail, each of the first, second, and third suction ducts 110, 120, and 130 comprises a ring-shaped bottom surface and a sidewall extending from the bottom surface to form a cylindrical shape. The second suction duct 120 surrounds the first suction duct 110 and is positioned to be spaced apart from the first suction duct 110. The third suction duct 130 surrounds the second suction duct 120 and is positioned to be spaced apart from the second suction duct 120.

The first, second, and third suction ducts 110, 120, and 130 provide recovery spaces RS1, RS2, and RS3 into which a treatment liquid scattered from the substrate “W” and an air flow including fumes are introduced. The first recovery space RS1 is defined by the first suction duct 110, the second recovery space RS2 is defined by the space between the first suction duct 110 and the second suction duct 120, and the third recovery space RS3 is defined by the space between the second suction duct 120 and the third duct 130.

The top surface of each of the first, second, and third suction ducts 110, 120, and 130 has an open central portion and an inclined surface, in which a distance between the inclined surface and a relevant bottom surface is gradually increased toward the open central portion from the sidewall connected with the top surface. Accordingly, the treatment liquid scattered from the substrate “W” flows into the recovery spaces RS1, RS2, and RS3 along the top surfaces of the first, second, and third suction ducts 110, 120, and 130.

A first treatment liquid introduced into the first recovery space RS1 is discharged to the outside through a first recovery line 141. A second treatment liquid introduced into the second recovery space RS2 is discharged to the outside through a second recovery line 143. A third treatment liquid introduced into the third recovery space RS3 is discharged to the outside through a third recovery line 145.

Meanwhile, the treatment container 100 is coupled to an elevating unit 600 to change the vertical position of the treatment container 100. The elevating unit 600 linearly moves the treatment container 100 in a vertical direction. As the treatment container 100 is moved in the vertical direction, the relative height of the treatment container 100 to a spin head 210 may be changed.

The elevating unit 600 comprises a bracket 612, a moving shaft 614, and a driving unit 616. The bracket 612 is fixedly installed on an outer wall of the treatment container 100. The moving shaft 614 moved by the driving unit 616 in the vertical direction is fixedly coupled to the bracket 612. When the substrate “W” is loaded to the spin head 210 or unloaded from the spin head 210, the treatment container 100 is moved down such that the spin head 210 protrudes upward from the treatment container 100. In addition, when a process is performed, the height of the treatment container 100 is adjusted such that a treatment liquid is introduced into the first to third suction ducts 110, 120, and 130 preset depending on the types of the treatment liquid supplied to the substrate W. Accordingly, the relative vertical position between the treatment container 100 and the substrate “W” is changed. Therefore, in the treatment container 100, a different treatment liquid and contaminated gas may be recovered for each of the recovery spaces RS1, RS2, and RS3.

According to the present embodiment, the process module 1 moves the treatment container 100 in the vertical direction to change the relative vertical position between the treatment container 100 and the substrate supporting member 200. However, the process module 1 may change the relative vertical position between the treatment container 100 and the substrate supporting member 200 by vertically moving the substrate supporting member 200.

The substrate supporting member 200 is installed inside the treatment container 100. The substrate supporting member 200 may support the substrate “W” during the process and may be rotated by the driving unit 230 to be described below while the process is performed. The substrate supporting member 200 comprises the spin head 210 having a circular top surface and comprises support pints 212 for supporting the substrate “W” and chucking pins 214 which are provided on the top surface of the spin head 210. The support pins 212 are arranged at regular distances while being spaced apart from each other on the edge part of the top surface of the spin head 210. The support pins 212 protrude upward from the spin head 210. The support pins 212 support the bottom surface of the substrate “W” such that the substrate “W” is supported while being spaced apart upward from the spin head 210. The chucking pins 214 are arranged outside the support pins 212 and provided to protrude upward. The chucking pints 214 align the substrate “W” such that the substrate “W” supported by the support pins 212 is placed on the right position of the spin head 210. When the process is performed, the chucking pins 214 make contact with the side portion of the substrate “W” to prevent the substrate “W” from being out of the right position. A heater 215 may be provided in the spin head 210 to heat the rinse liquid supplied onto the substrate W.

A support shaft 220 is coupled to the lower portion of the spin head 210 to support the spin head 210. The support shaft 220 rotates by the driving unit 230 coupled to the lower end of the support shaft 220. The driving unit 230 may comprise a motor. As the support shaft 220 rotates, the spin head 210 and the substrate “W” rotate.

The spray member 300 receives the rinse liquid in the treatment process for substrate “W” and sprays the rinse liquid onto the treatment surface of the substrate “W” placed on the spin head 210 of the substrate supporting member 200. The spray member 300 comprises a support shaft 310, a driver 320, a nozzle support 340, and a spray nozzle 342.

The length direction of the support shaft 310 is the vertical direction, and the lower end of the support shaft 310 is coupled to the driver 320. The driver 320 changes the position of the support shaft 310 or rotates the support shaft 310. The nozzle support 340 is coupled to the support shaft 310 to move the spray nozzle 342 to the upper portion of the substrate “W” or moves the spray nozzle 342 to the upper portion of the substrate “W” while the spray nozzle 342 is spraying the rinse liquid.

The spray nozzle 342 is installed on the bottom surface of the end portion of the nozzle support 340. The spray nozzle 342 is moved to a process position and a standby position by the driver 320. The process position is a position at which the spray nozzle 342 is arranged at the vertical upper portion of the treatment container 100, and the standby position is a position at which the spray nozzle 342 is out of the vertical upper portion of the treatment container 100. The spray nozzle 342 sprays the rinse liquid. When the rinse liquid is pure water, the process module 1 may further comprise a nozzle for supplying a chemical liquid to the substrate W. In this case, the chemical liquid supplied to the substrate “W” may be a chemical liquid for cleaning the substrate “W” or a chemical liquid for etching the substrate W. In addition, when the rinse liquid is isopropyl alcohol, the process module 1 may further comprise a nozzle for supplying a chemical liquid to the substrate “W” and a nozzle for supplying pure water to the substrate “W” after treating the substrate “W” using the chemical liquid. In this case, the chemical liquid supplied to the substrate “W” may be a chemical liquid for cleaning the substrate “W” or a chemical liquid for etching the substrate W.

The exhaust line 410 is to discharge the internal gas of the treatment container 100. A fan filter unit 810 may be positioned at an upper portion of the chamber 800 to supply gas, which is for forming a downstream air flow, to the inner space of the chamber 800.

A pressurizing line 821 is connected with the chamber 800 to increase the internal pressure of the chamber 800. The pressurizing line 821 may be connected to a supply port 822 formed in the process region 815 in which the substrate “W” is treated. The pressurizing line 821 is coupled to a gas supply unit 823. The gas supply unit 823 supplies pressurizing gas for pressurizing the inner part of the chamber 800. The pressurizing gas may include inert gas such as nitrogen (N) or argon (Ar). The pressurizing gas supplied by the gas supply unit 823 has been already heated to a preset temperature. In addition, a line heater 825 may be positioned on the pressurizing line 821 to heat the pressurizing gas which is supplied. Accordingly, the line heater 825 may prevent the temperature of a pressurizing fluid flowing through the pressurizing line 821 from being lowered. In addition, the gas supply unit 823 may supply the pressurizing fluid at a normal temperature and the pressurizing fluid may be heated in the procedure of being supplied through the pressurizing line 821. A pressurizing valve 824 may be positioned on the pressurizing line 821.

A depressurizing line 831 is connected with the chamber 800 to reduce the pressure of the inner space of the chamber 800. The depressurizing line 831 may be connected to a discharge port 832 formed in the process region 815 in which the substrate “W” is treated. The depressurizing line 831 may be connected with a pump 833 which provides vacuum for forcibly exhausting the gas of the inner part of the chamber 800. A depressurizing valve 834 may be positioned on a depressurizing line 831.

FIG. 3 is a view illustrating a pipe relation of the spray member.

Referring to FIG. 3, the spray nozzle 342 is connected with a rinse liquid tank 343 through a supply pipe 344. A valve 345 may be positioned at the side of the rinse liquid tank 343. The supply pipe 344 is to supply the rinse liquid, which is heated to a preset temperature, to the spray nozzle 342. For example, a pipe heater 346 may be positioned on the supply pipe 344. Accordingly, the rinse liquid may be heated to the preset temperature by the pipe heater 346 in the procedure that the rinse liquid is supplied through the supply pipe 344. In addition, the rinse liquid tank 343 may be provided to supply a rinse liquid to the supply pipe 344 after heating the rinse liquid to the preset temperature. Further, the rinse liquid tank 343 may be provided to supply a rinse liquid to the supply pipe 344 after heating the rinse liquid to the preset temperature and may prevent the rinse liquid from being lowered by the pipe heater 346 in the procedure that the rinse liquid is supplied. When the heated rinse liquid is supplied, the temperature of the rinse liquid may be supplied to be higher than a boiling point of the rinse liquid under the atmospheric pressure. In addition, to prevent the rinse liquid from being vaporized, the internal pressure of the supply pipe 344 may be maintained in a pressure range for maintaining the rinse liquid in a liquid phase.

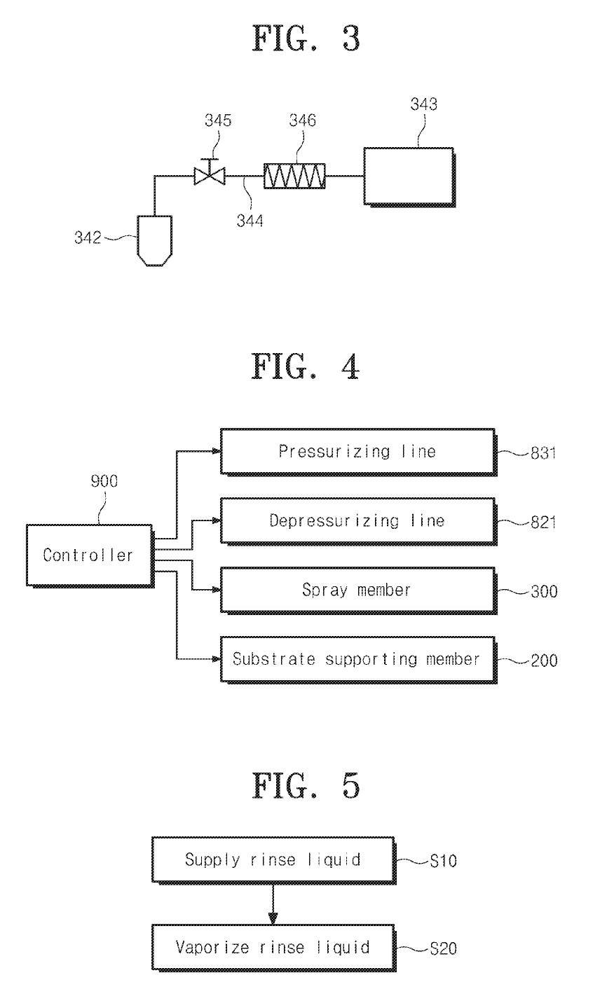

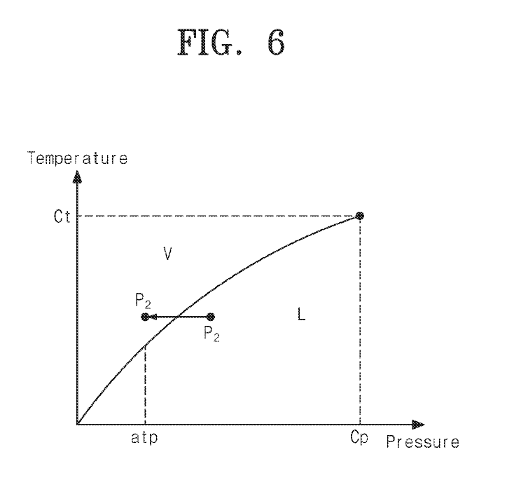

FIG. 4 is a view illustrating the control relation of the process module, FIG. 5 is a view illustrating the procedure of rinsing and drying the substrate, and FIG. 6 is a view illustrating a vaporization graph of a part in which the drying procedure is performed.

Referring to FIGS. 4 to 6, a controller 900 controls the process module 1 to vaporize a rinse liquid after supplying the rinse liquid to the substrate W.

The rinse liquid is applied to the substrate “W” at the final stage of substrate liquid treatment. When the rinse liquid is isopropyl alcohol, a chemical liquid may be supplied to the substrate “W” for the treatment such as the cleaning or the etching of the substrate “W” before applying the isopropyl alcohol to the substrate W. Then, pure water may be supplied to the substrate “W” to remove remaining chemical liquid and foreign matters from the substrate W. Thereafter, when the isopropyl alcohol is supplied to the substrate “W”, the pure water remaining on the substrate “W” may be substituted with the isopropyl alcohol. When the rinse liquid is pure water, a chemical liquid may be supplied to the substrate “W” for the treatments such as the cleaning or the etching of the substrate “W” before applying the pure water to the substrate W. Thereafter, when the pure water is supplied to the substrate “W”, the chemical liquid and foreign matters remaining on the substrate “W” are removed.

The controller 900 controls the pressuring line 831 and the spray member 300 in the state that the internal pressure of the chamber 800 is maintained to be set pressure or pressure in a set range by the pressurizing gas. The set pressure or the pressure in the set range is provided to be higher than atmospheric pressure and to be lower than critical pressure of the rinse liquid. The rinse liquid may be supplied to the substrate “W” at a set temperature or a temperature in a set range. The set temperature or the temperature in the set range is provided to be higher than a boiling point of the rinse liquid and lower than a supercritical temperature under the atmospheric pressure. In addition, the set temperature or the temperature in the set range is provided to a temperature for maintaining the rinse liquid in a liquid phase under the internal pressure of the chamber 800. A set amount of the rinse liquid may be supplied to the substrate “W” for a set time. In addition, the rinse liquid may be supplied in several steps. In the first supply step, the rinse liquid may be supplied to the substrate “W” in the state that the rinse liquid is not heated. Thereafter, in the second supply step, the rinse liquid, which is heated to a temperature set to be higher than the temperature in the first supply step, may be supplied to the substrate W. In the first supply step, the pressurizing gas is not supplied into the chamber 800 as the controller 900 closes the pressurizing valve 824. Alternatively, in the first supply step, the pressurizing gas is supplied into the chamber 800 and thus the internal pressure of the chamber 800 is adjusted to the set pressure or the pressure in the set range. Further, in the first supply step, the internal pressure of the chamber 800 may be the set pressure or the pressure in the set range. Further, in the second supply step, the internal pressure of the chamber 800 may be provided to the set pressure or the pressure in the set range. When the rinse liquid is supplied, the controller 900 allows the heater 215 to heat the rinse liquid.

Thereafter, the controller 900 controls the depressurizing line 831 to exhaust internal gas of the chamber 800 such that the surrounding pressure of the substrate “W” is lowered. The exhausting of the gas is performed such that the internal pressure of the chamber 800 is rapidly reduced within a short time of period. Accordingly, in the state that the internal temperature of the chamber 800 and the temperature of the rinse liquid are identically maintained or are minimized in change, the pressure of the chamber 800 is reduced. As the pressure of the chamber 800 is reduced, the internal state of the chamber 800 is moved from a point P2 that the rinse liquid is in a liquid phase to a point P2 that the rinse liquid is in a gas phase. Accordingly, the remaining rinse liquid on the substrate “W” is rapidly vaporized. In addition, as the internal gas of the chamber 800 is exhausted, the vaporized rinse liquid is discharged from the chamber 800.

According to an embodiment of the inventive concept, the rinse liquid is removed from the substrate “W” in that the surface tension is reduced. According to Eotvos or Ramsay Shield's Equation, the surface tension of the rinse liquid is decreased depending on the temperatures of the rinse liquid. According to the inventive concept, the vaporization of the rinse liquid is made by increasing pressure at the temperature which is higher than the boiling point under the atmospheric pressure. Accordingly, when the rinse liquid is vaporized, the rinse liquid is provided in that the surface tension is reduced.

In addition, according to an embodiment of the inventive concept, since the rinse liquid is vaporized in the state that the surface tension is reduced, various fluids, such as isopropyl alcohol and pure water may be used.

As described above, according to an embodiment of the inventive concept, there may be provided a substrate treating apparatus and a substrate treating method, capable of efficiently treating the substrate.

In addition, according to an embodiment of the inventive concept, there may a substrate treating apparatus and a substrate treating method, capable of efficiently drying the rinse liquid applied to the substrate.

The above description has been made for the illustrative purpose. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. The written embodiment describes the best state for implementing the technical spirit of the inventive concept, and various changes required in the detailed application fields and purposes of the inventive concept can be made. Furthermore, it should be construed that the attached claims include other embodiments.

What is claimed is:

1. An apparatus for treating a substrate, the apparatus comprising:
a chamber;
a substrate supporting member which is positioned in the chamber to support the substrate;
a spray member which supplies a rinse liquid to the substrate;
a depressurizing line which is used to depressurize the chamber; and
a controller which vaporizes the rinse liquid by depressurizing the chamber through the depressurizing line after supplying the rinse liquid.

2. The apparatus of claim 1, wherein the spray member supplies a rinse liquid heated to a set temperature.

3. The apparatus of claim 1, wherein the controller controls the spray member to supply the rinse liquid in a first supply step of supplying the rinse liquid to the substrate and in a second supply step of supplying a rinse liquid heated to a temperature higher than a temperature of the rinse liquid in the first supply step.

4. The apparatus of claim 1, wherein the apparatus further comprise
a pressurizing line connected with the chamber to supply pressurizing gas, which is used for pressurizing an inner part of the chamber, to the inner part of the chamber.

5. The apparatus of claim 4, wherein a line heater is provided on the pressurizing line to heat the pressurizing gas.

6. The apparatus of claim 4, wherein the pressurizing gas, which is supplied to the inner part of the chamber, is provided in a state that the pressurizing gas is heated to a set temperature.

7. The apparatus of claim 4, wherein the controller controls the pressurizing line such that internal pressure of the chamber is higher than atmospheric pressure and lower than critical pressure of the rinse liquid, when supplying the rinse liquid.

8. The apparatus of claim 1, wherein the rinse liquid has a temperature higher than a boiling point under atmosphere pressure and lower than a boiling point under internal pressure of the chamber.

9. The apparatus of claim 1, wherein the rinse liquid is pure water.

10. The apparatus of claim 1, wherein the rinse liquid is isopropyl alcohol.

11. The apparatus of claim 1, wherein the spray member comprises:
a spray nozzle which discharges the rinse liquid to the substrate;
a rinse liquid supply unit which supplies the rinse liquid; and
a supply pipe which connects the rinse liquid supply unit with the spray nozzle, and
wherein the rinse liquid supply unit and the supply pipe have pressure higher than atmospheric pressure.

12. The apparatus of claim 1, wherein the substrate supporting member comprises a heater to heat the rinse liquid applied to the substrate.

13. A method for treating a substrate, the method comprising:
positioning the substrate in a chamber having pressure higher than atmospheric pressure;
supplying, to the substrate, a rinse liquid, which is heated to a temperature higher than a boiling point under atmospheric pressure, in a liquid phase; and
vaporizing the rinse liquid by depressurizing the chamber.

14. The method of claim 13, wherein internal pressure of the chamber is provided to be lower than critical pressure of the rinse liquid.

15. The method of claim 13, wherein the rinse liquid is pure water.

16. The method of claim 13, wherein the rinse liquid is isopropyl alcohol.

17. The method of claim 13, wherein the pressurizing of the chamber is performed by supplying heated inert gas.

18. A method for treating a substrate, the method comprising:
supplying a rinse liquid to the substrate;
supplying a rinse liquid, which is heated, in a state that internal pressure of the chamber is higher than atmospheric pressure; and
vaporizing the rinse liquid by depressurizing the chamber.
